(19) United States
(12) Patent Application Publication
(10) Pub. No.: US 2019/0014683 A1
(43) Pub. Date: Jan. 10, 2019

(54) WIRELESS CHARGER WITH STRUCTURE FOR DIRECTLY COOLING PORTABLE TERMINAL

(71) Applicant: CPC Co., Ltd., Hwaseong-si (KR)

(72) Inventor: HYUN SUK HAN, Incheon (KR)

(73) Assignee: CPC Co., Ltd., Hwaseong-si (KR)

(21) Appl. No.: 15/961,898

(22) Filed: Apr. 25, 2018

(30) Foreign Application Priority Data
Jul. 10, 2017 (KR) 10-2017-0086962

(51) Int. Cl. H05K 7/20; H02J 7/02; H02J 7/00

(52) U.S. Cl. CPC H05K 7/20145; H02J 50/10; H02J 7/0044; H02J 7/025

(57) ABSTRACT

According to an aspect of the present disclosure, a wireless charger for wirelessly charging a portable terminal, having a structure for directly cooling the portable terminal, includes: a charging body on which the portable terminal to be charged is put; a top hole which is formed to penetrate a top of the charging body and makes air between the portable terminal put on the charging body and the charging body flow into the charging body so that the portable terminal can be directly cooled; a cooling fan by which the air between the portable terminal put on the charging body and the charging body is introduced into the charging body; and an outlet hole through which the air introduced into the charging body by the cooling fan is discharged outward from the charging body.

### CROSS-REFERENCE TO RELATED APPLICATION

This application claims priority from Korean Patent Application No. 10-2017-0086962, filed on Jul. 10, 2017 in the Korean Intellectual Property Office, the disclosure of which is incorporated herein by reference.

### BACKGROUND OF THE INVENTION

### (a) Field of the Invention

The present disclosure relates to a wireless charger having a structure for directly cooling a portable terminal.

### (b) Description of the Related Art

A wireless charger refers to a device for charging a terminal without contact, and is classified into a magnetic induction type and a magnetic resonance type. In general, the wireless charger used in charging a smartphone is the magnetic induction type.

A general wireless charger is internally provided with a coil and the like of generating heat, and thus additionally includes an internal cooling fan and a ventilation hole to dissipate the generated heat. However, a conventional wireless charger available on the market these days has a structure for merely dissipating its own heat. In other words, such a wireless charger cannot lower temperature of a portable terminal being charged.

### SUMMARY OF THE INVENTION

Accordingly, the present disclosure is conceived to solve the foregoing problems, and an aspect of the present disclosure is to effectively dissipate heat generated while a wireless charger is charging a portable terminal, and thus provide a wireless charger having a structure for directly cooling a portable terminal, in which the existing built-in cooling fan for dissipating heat generated in the wireless charger can dissipate not only the heat generated in the wireless charger but also heat generated in the portable terminal.

In accordance with an embodiment of the present disclosure, there is provided a wireless charger for wirelessly charging a portable terminal, having a structure for directly cooling the portable terminal, including: a charging body on which the portable terminal to be charged is put; a top hole which is formed to penetrate a top of the charging body and makes air between the portable terminal put on the charging body and the charging body flow into the charging body so that the portable terminal can be directly cooled; a cooling fan by which the air between the portable terminal put on the charging body and the charging body is introduced into the charging body; and an outlet hole through which the air introduced into the charging body by the cooling fan is discharged outward from the charging body.

### BRIEF DESCRIPTION OF THE DRAWINGS

The above and/or other aspects of the present disclosure will become apparent and more readily appreciated from the following description of the exemplary embodiments, taken in conjunction with the accompanying drawings, in which:

FIG. 1 is a schematic cross-section view of a wireless charger having a structure for directly cooling a portable terminal according to a first embodiment of the present disclosure;

FIG. 2 is a cross-section view of showing that the portable terminal is put on the wireless charger shown in FIG. 1;

FIG. 3 is a plan view of FIG. 1;

FIG. 4 is a perspective view of FIG. 1;

FIG. 5 is a perspective view of FIG. 2;

FIGS. 6 and 7 are a cross-section view and a plan view of showing flow of air while a cooling fan is operating;

FIGS. 8 and 9 are graphs of showing results of experiments on temperature change of batteries when an inventive wireless charger according to the present disclosure and comparative wireless chargers are used in charging the battery;

FIG. 10 is a schematic cross-section view of a wireless charger having a structure for directly cooling a portable terminal according to a second embodiment of the present disclosure;

FIG. 11 is a cross-section view of showing that the portable terminal is put on the wireless charger shown in FIG. 10;

FIG. 12 is a perspective view of FIG. 10;

FIG. 13 is a schematic cross-section view of a wireless charger having a structure for directly cooling a portable terminal according to a third embodiment of the present disclosure;

FIG. 14 is a schematic cross-section view of a wireless charger having a structure for directly cooling a portable terminal according to a fourth embodiment of the present disclosure;

FIG. 15 is an enlarged view of ‘A’ in FIG. 14;

FIGS. 16 and 17 are enlarged cross-section views of showing flow of air in FIG. 14;

FIG. 18 is a schematic cross-section view of a wireless charger having a structure for directly cooling a portable terminal according to a fifth embodiment of the present disclosure;

FIG. 19 is an enlarged view of ‘B’ in FIG. 18;

FIG. 20 is schematic cross-section view of a wireless charger having a structure for directly cooling a portable terminal according to a sixth embodiment of the present disclosure; and

FIG. 21 is a perspective view of FIG. 20.

### DETAILED DESCRIPTION

Below, embodiments of a wireless charger having a structure for directly cooling a portable terminal according to the present disclosure will be described with reference to the accompanying drawings.

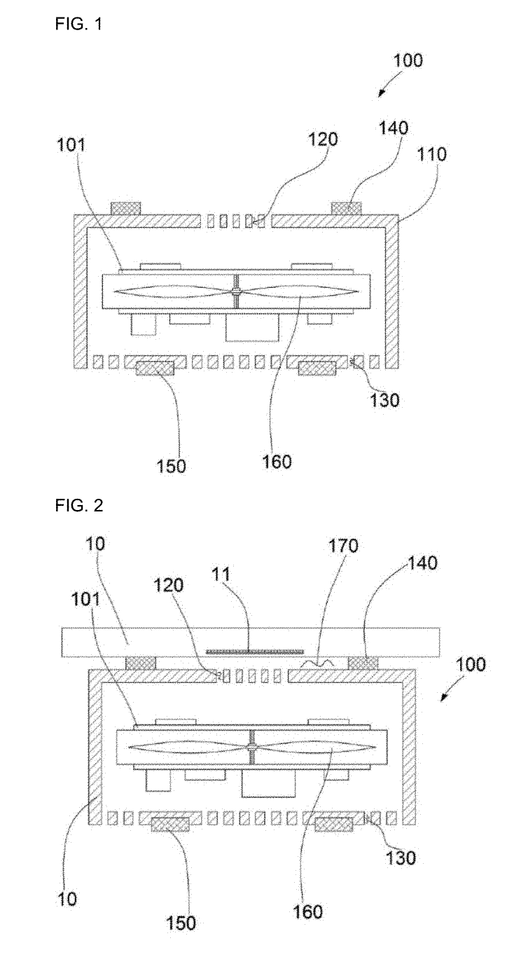

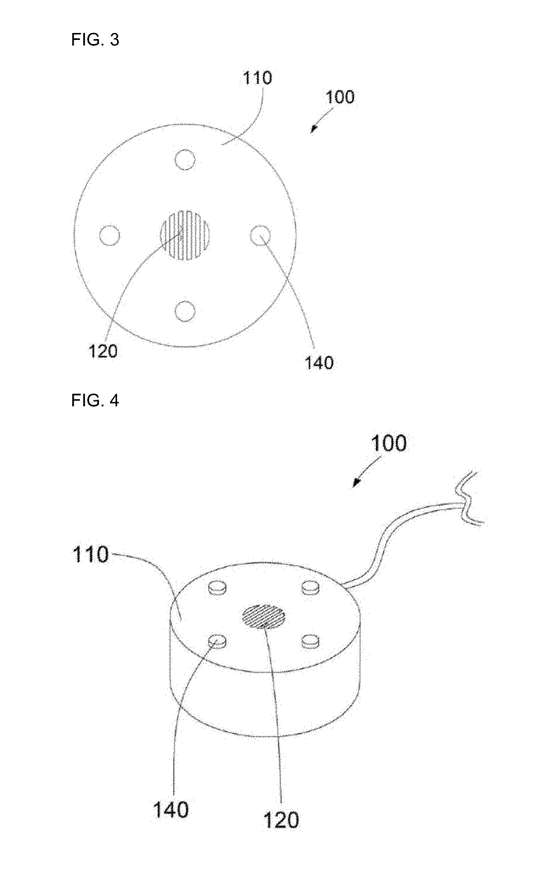

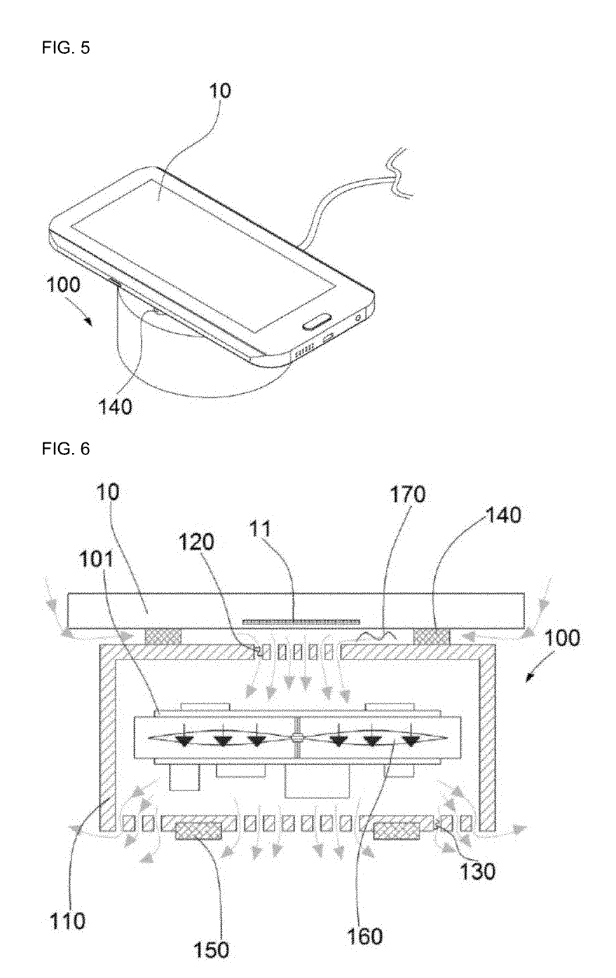

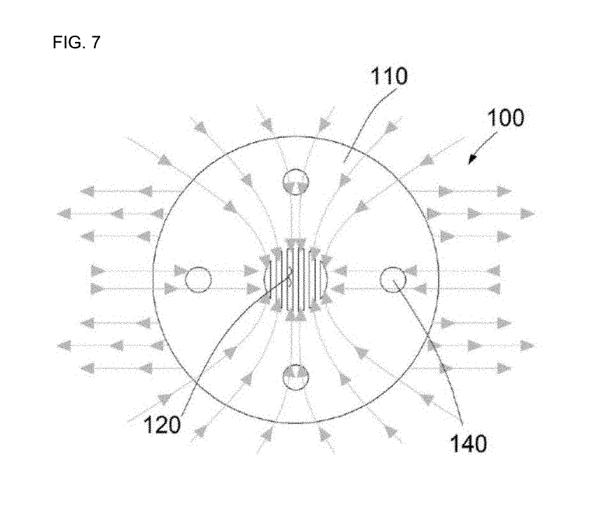

Referring to FIGS. 1 to 9, a wireless charger having a structure for directly cooling a portable terminal according to a first embodiment of the present disclosure includes a charging body 110, a cooling fan 160, a top hole 120, and an outlet hole 130 as a structure to be applicable to a wireless charger 100 for wirelessly charging a portable terminal 10.

The portable terminal 10 includes a charging patch 11 attached thereto and receiving electric power from a power transmission coil 101 of the wireless charger 100 to charge a battery. While the portable terminal 10 is being wirelessly charged by the wireless charger 100, the charging patch 11 generates heat and thus makes the portable terminal 10 hot.

The charging body 110 is used to put the portable terminal 10 thereon for charging, and is internally provided with the cooling fan 160 (to be described later. The charging body 110 is formed with the top hole 120 on the top thereof, through which air between the portable terminal 10 put on the charging body 110 and the portable terminal 10 is introduced into the charging body 110 so that the portable terminal can be directly cooled.

As shown in FIG. 1, a plurality of top holes 120 may be formed leaving a space there between on the top of the charging body 110. Here, the charging patch 11 is generally attached to the center of the portable terminal 10, and thus put on the top center of the wireless charger 100 when the portable terminal 10 is put on the wireless charger 100. Therefore, the top hole 120 is also formed on the top center of the charging body 110 as shown in FIG. 2.

The cooling fan 160 is configured to introduce air between the portable terminal 10 put on the charging body 110 and the charging body 110 into the charging body 110, and is thus arranged inside the charging body 110 as shown in FIG. 1 so as to dissipate heat generated by the power transmission coil 101.

When the cooling fan 160 is operating, air between the portable terminal 10 put on the charging body 110 and the charging body 110 comes in the charging body 110 and then goes out through the outlet hole 130.

The outlet hole 130 is configured to make air introduced into the charging body 110 by the cooling fan 160 go out of the charging body 110. In this embodiment, the outlet hole 110 is formed to connect the inside and outside of the charging body 110 at the bottom so that air inside the charging body 110 can be discharged outward from the charging body 110 through the bottom of the charging body 110. Alternatively, the outlet hole 110 may be formed at various portions, for example, the lateral sides of the charging body 110.

The outlet hole 130 may be formed to have a size for preventing external dust or various foreign materials from entering the inside of the charging body 110. As shown in FIG. 1, a plurality of outlet holes 130 may be formed leaving a space there between so that air inside the charging body 110 can be smoothly discharged to the outside.

The reference numeral of ‘150’ indicates a projection that protrudes outward from the bottom of the charging body 110 to have a predetermined height and prevent close contact between the opening portion of the outlet hole 130 and an installation surface (not shown). Here, the installation surface refers to a place where the wireless charger 100 is installed, and may include a desk, a floor, etc.

Such support projections 150 may be provided in plural being spaced apart from one another and protrude from the bottom of the charging body 110, in which the center of the plural support projections 150 is aligned with the bottom center of the charging body 110, thereby stably supporting the wireless charger.

The charging body 110 is provided with a direct cooling projection 140 protruding at a predetermined height to form a gap 170 through which air can flow between the charging body 110 and the portable terminal 10 when the portable terminal 10 to be charged is put on the charging body 110.

Such direct cooling projections 140 may be provided in plural being spaced apart from one another and protrude from the top of the charging body 110 at the same height, in which the protruding height of the direct cooling projection 140 is variable without affecting the wireless charge of the portable terminal 10. With this structure, air in the gap 170 can be introduced into the charging body 110 through the top hole 120 when the portable terminal 10 to be charged is put on the top of the direct cooling projection 140.

Specifically, when the portable terminal 10 to be charged is put on the top of the direct cooling projection 140, the charging patch 11 of the portable terminal 10 may be positioned straightly above the top hole 120. At this position, heat generated by the charging patch 11 makes the portable terminal 10 be heated and thus causes the temperature of air in the gap 170 to rise. The air raised in temperature is inhaled into the charging body 110 by the cooling fan 160 through the top hole 120. Then, new air is introduced into the gap 170. In this manner, air is circulated in the gap 170. That is, the air raised in temperature by the heat of the portable terminal 10 does not remain in the gap 170 but flows into the charging body 110 by the cooling fan 160, so that new air having a relatively low temperature can be introduced into the gap 170, thereby cooling the warmed portable terminal 10.

Below, a process of cooling the portable terminal 10 heated by the charging patch 11 while the portable terminal 10 is wirelessly charging by the wireless charger 100 will be described.

First, the portable terminal 10 is placed on the direct cooling projection 140 of the wireless charger 100. In this case, the charging patch 11 is arranged straightly above the top hole 120. Then, the portable terminal 10 starts charging wirelessly, and at the same time the cooling fan 160 operates. Further, the portable terminal 10 starts generating heat as the power transmission coil 101 and the charging patch 11 generate heat.

As shown in FIG. 6, the cooling fan 160 draws air in the gap 170 into the charging body 110 through the top hole 120, and thus the drawn air and air staying inside the charging body 110 and raised in temperature by the power transmission coil 101 are discharged together to the outside of the charging body 110 through the outlet hole 130.

Here, air in the gap 170 is raised in temperature due to heat of the portable terminal 10, and stops staying. As new air flows into the gap 170, air circulation occurs to thereby have an effect on cooling the warmed portable terminal 10. In other words, the structure of the wireless charger for directly cooling the portable terminal has merits of cooling both the portable terminal 10 and the power transmission coil 101 through the cooling fan 160 of the wireless charger 100 without any additional device for cooling the portable terminal 10. Further, it is possible to solve device defects or the like problem caused by the heat generated in the portable terminal 10 during wireless charging

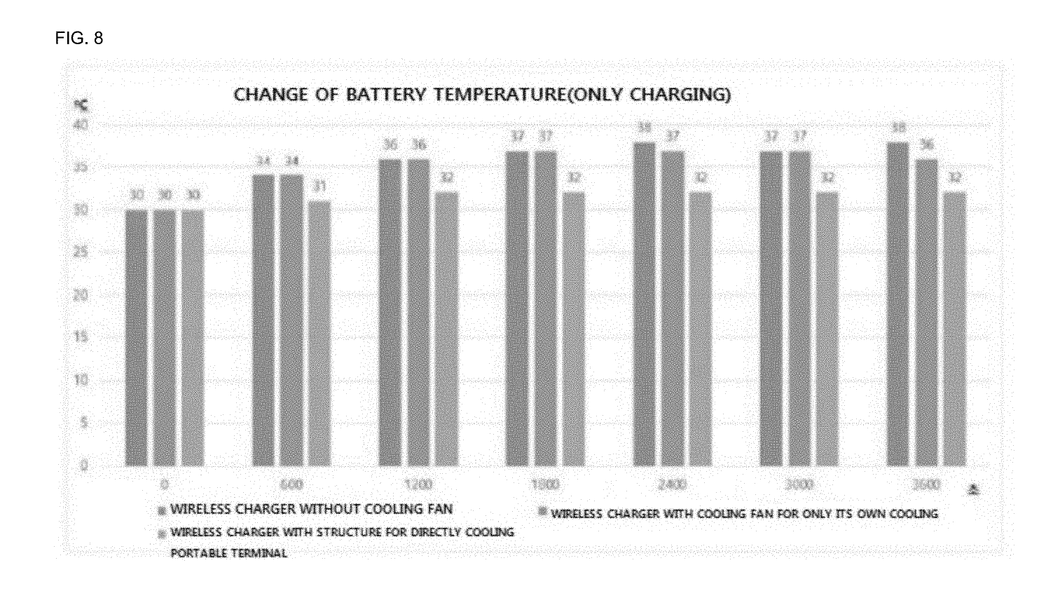

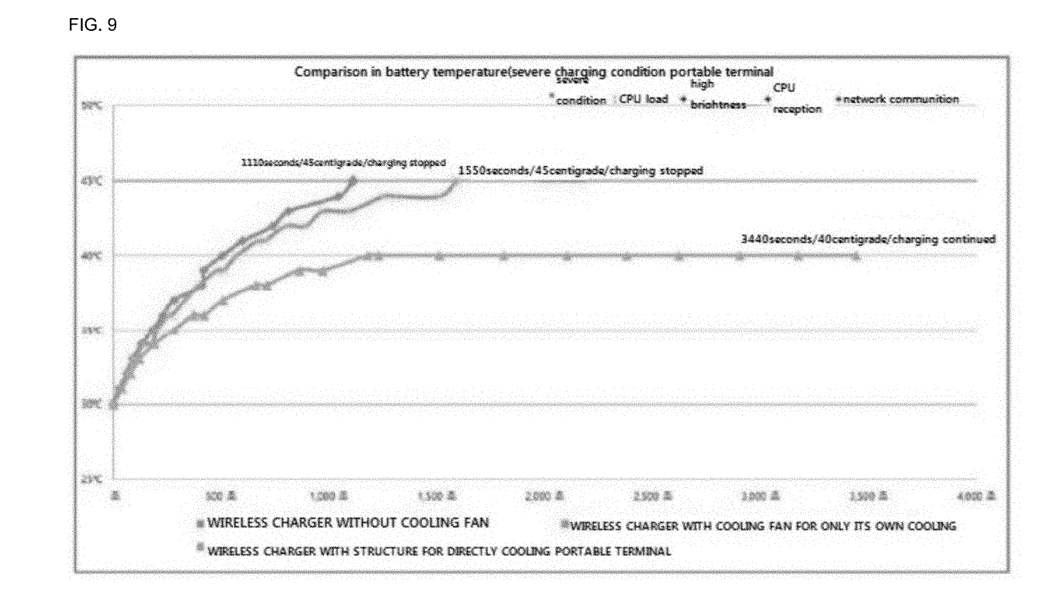

Below, results of experiments on temperature change of batteries when the inventive wireless charger 100 and comparative wireless chargers are used in charging the battery will be described with reference to graphs of FIGS. 8 and 9.

Referring to the graph of FIG. 8, it will be appreciated that the battery temperature of the portable terminal 10 in the wireless charger 100 having the structure for directly cooling the portable terminal 10 according to one embodiment of the present disclosure is lower than that in the general wireless chargers having no structures for directly cooling the portable terminal 10.

Further, referring to the graph of FIG. 9, as results of the experiments, it will be understood that the battery temperature of the portable terminal 10 in the wireless charger 100 having the structure for directly cooling the portable terminal 10 according to one embodiment of the present disclosure rises more gently than that in the general wireless chargers having no structures for directly cooling the portable terminal 10.

Specifically, the general wireless chargers having no structures for directly cooling the portable terminal 10 make the temperature of the battery reach a preset maximum allowable temperature of 45° C., and therefore that wireless charging is stopped so that the battery cannot generate heat any more. On the other hand, the wireless charger 100 having the structure for directly cooling the portable terminal 10 does not make the temperature of the portable terminal 10 reach the preset maximum allowable temperature and thus makes the portable terminal 10 be charging wirelessly until the portable terminal 10 is fully charged.

Here, the maximum allowable temperature refers to a temperature at which device defects and the like abnormalities occur in the portable terminal 10 or the wireless charger 100. In other words, the wireless charger 100 according to the present disclosure directly cools the portable terminal 10 and prevents the temperature of the portable terminal 10 from reaching the preset maximum allowable temperature, thereby making the portable terminal 10 be charging wirelessly until the portable terminal 10 is fully charged.

Below, a wireless charger having a structure for directly cooling a portable terminal according to another embodiment of the present disclosure will be described with reference to the accompanying drawings. Here, repetitive descriptions, which have already been disclosed in the foregoing embodiment, will be avoided as necessary.

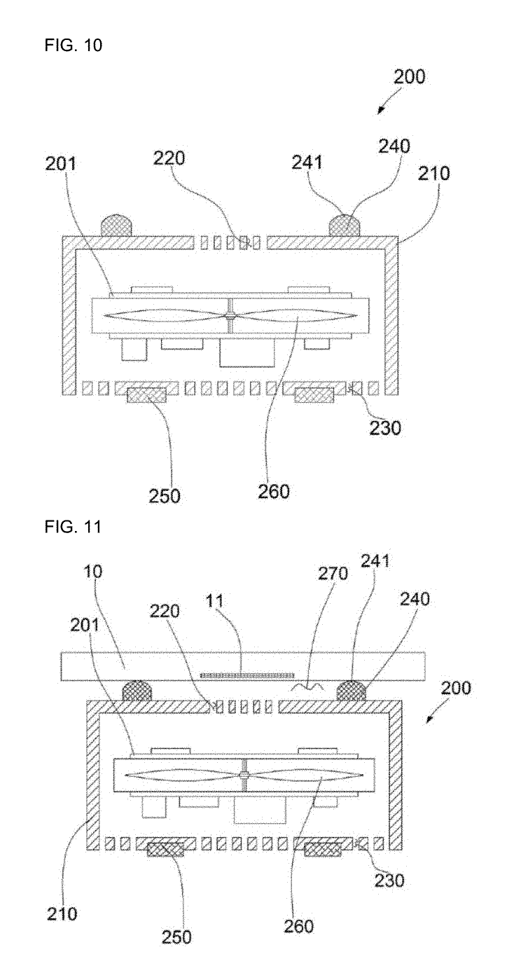

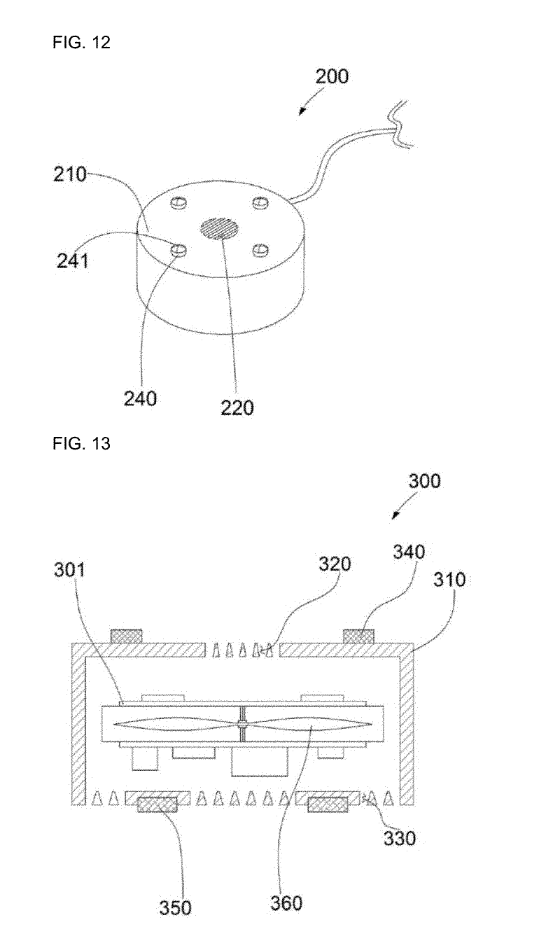

Referring to FIGS. 10 to 12, a direct cooling projection 240 according to a second embodiment of the present disclosure protrudes at a predetermined height from the top of a charging body 210. A plurality of direct cooling projections 240 are spaced apart from one another and protrude from the top of the charging body 210 at the same height,

Such an upper direct cooling projection 240 is formed with a point contact portion 241 protruding outwardly and convexly from the top thereof. As shown in FIG. 11, when the portable terminal 10 is placed on the direct cooling projection 240, the bottom of the portable terminal 10 is in point-contact with the point contact portion 241.

Thus, when the portable terminal 10 is put on the direct cooling projection 240, a contact area between the direct cooling projection 240 and the portable terminal 10 is smaller than the area of surface contact. Accordingly, a gap 270 in which air can circulate under the portable terminal 10 is larger, and therefore a cooling fan 260 can more effectively cool the portable terminal 10.

FIG. 13 is a schematic cross-section view of a wireless charger having a structure for directly cooling a portable terminal according to a third embodiment of the present disclosure;

Referring to FIG. 13, according to the third embodiment of the present disclosure, a top hole 320 is formed to have a trapezoidal shape that becomes wider in a direction from an inner opening side of the charging body 310 toward an outer opening side of the charging body 310, and the outlet hole 330 is formed to have a trapezoidal shape that becomes narrower in a direction from an inner opening side of the charging body 310 toward an outer opening side of the charging body 310.

With this structure, a large amount of air in the gap can be introduced into the relatively wide opening side of the top hole 320, and a large amount of air in the charging body 310 is discharged through the relatively wide opening side of the outlet hole 330. Then, air in the gap and the charging body 310 is more quickly circulated, and it is thus possible to quickly lower the temperature of the power transmission coil 301 or the portable terminal.

Further, the relatively narrow opening side of the top hole 320 or the relatively narrow opening side of the outlet hole 330 can prevent external dust and the like foreign materials from entering the charging body 310.

Next, a wireless charger having a structure for directly cooling a portable terminal according to a fourth embodiment of the present disclosure will be described.

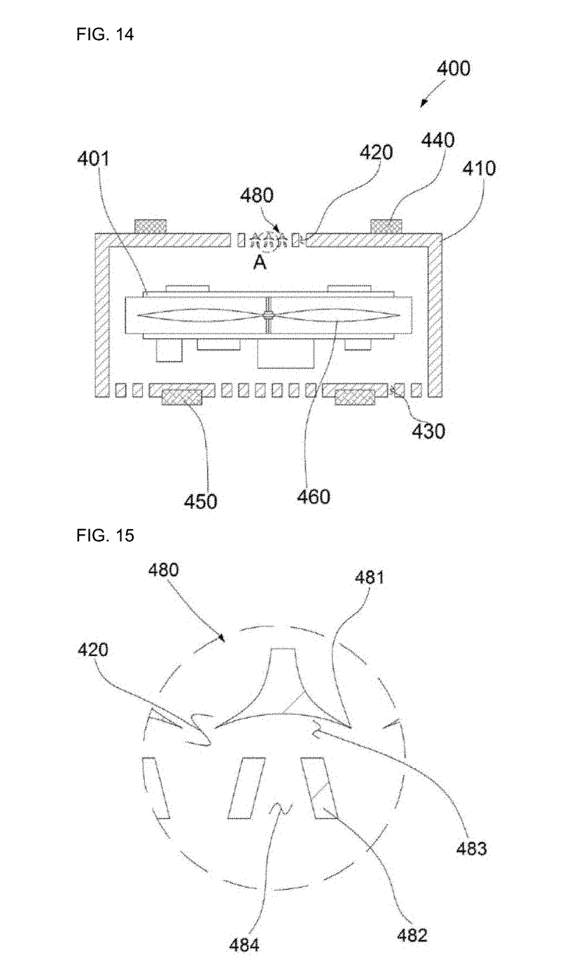

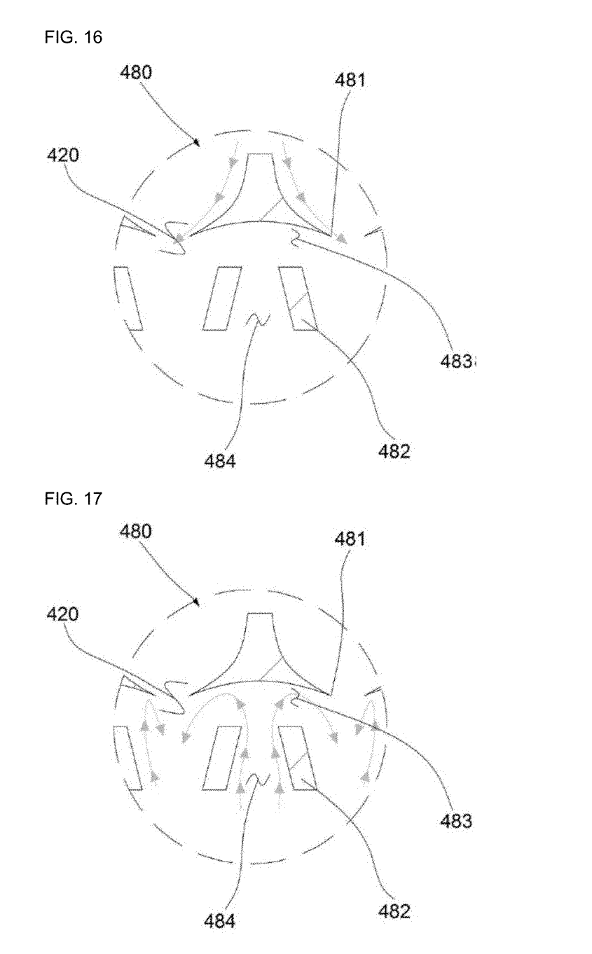

Referring to FIGS. 14 to 17, the wireless charger having a structure for directly cooling a portable terminal according to a fourth embodiment of the present disclosure includes a charging body 410, a cooling fan 460, a top hole 420, an outlet hole 430, and an eddy member 480 as a structure to be applicable to a wireless charger 400 for wirelessly charging a portable terminal 10.

The eddy member 480 includes an incoming eddy eave 481, and an incoming eddy body 482, which are formed between a plurality of top holes 420, and guide air in the charging body 410 eddy and go back to the inside of the charging body 410 when the air in the charging body 410 is discharged outward from the charging body 410 via the top hole 420.

The incoming eddy eave 481 is capable of changing a direction of air in the top hole 420 toward the inside of the charging body 410 when air in the charging body 410 is discharged outward from the charging body 410.

The incoming eddy bodies 482 constitute the eddy member 480 and form an air flowing hole 484 through which air can flow from the inside of the charging body 410 toward the top hole 420 of the charging body 410. The air flowing hole 484 is larger at the inward opening side of the charging body 410 than that at the other opening side to thereby generally form a trapezoidal shape like the trapezoidal cross-section of the incoming eddy body 482.

In the eddy member 480, the inclined inner walls of the incoming eddy bodies 482 are formed with an air discharge hole 483 which communicates with the air flowing hole 484 so that air flowing through the air flowing hole 484 can be discharged into the top hole 420. Here, air discharged from the air discharge hole 483 may eddy by the incoming eddy eave 481 and go back to the inside of the charging body 410 as shown in FIG. 17.

With this structure, air inside the charging body 410 is prevented from flowing outward through the top hole 420. Thus, for example, when hot air inside the charging body 410 flows out through the top hole 420 and affects the portable terminal as the portable terminal to be wirelessly charged is put on the charging body 410, the eddy member 480 guides the air to eddy toward the inside of the charging body 410 and return back to the charging body 410, thereby having effects on discharging the air to the outside of the charging body 410 via not the top hole 420 but the outlet hole 430.

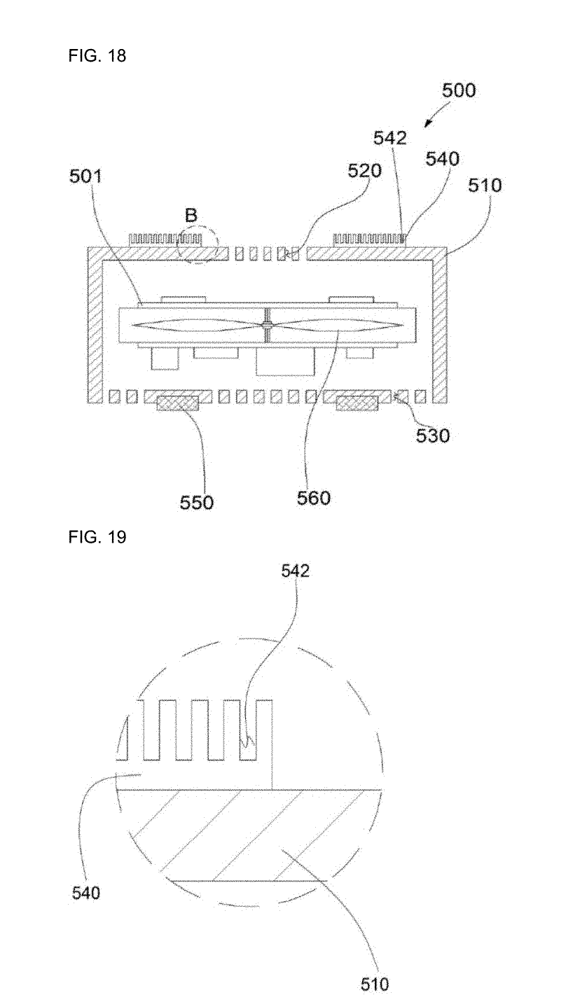

FIGS. 18 and 19 show a wireless charger having a structure for directly cooling a portable terminal according to a fifth embodiment of the present disclosure.

As shown in FIG. 18 and FIG. 19, a direct cooling projection 540 according to the fifth embodiment of the present disclosure is made of a conductive material capable of absorbing thermal energy, and is formed with a plurality of heat dissipation grooves 542 thereon at regular intervals to dissipate heat from the direct cooling projection 540. The direct cooling projection 540 may be made of copper or the like metal having good thermal conductivity.

With this structure, when the portable terminal to be wirelessly charged is put on the direct cooling projection 540, thermal energy of the portable terminal is transferred to the direct cooling projection 540. In this state, air starts to flow and circulate around the heat dissipation groove 542, thereby having effects on dissipating the thermal energy from the direct cooling projection 540.

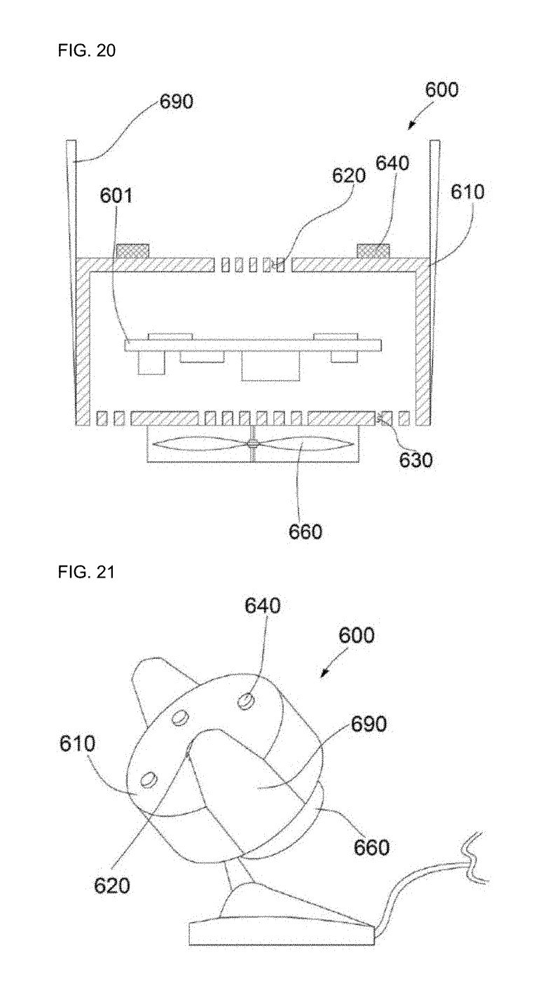

FIGS. 20 and 21 show a wireless charger having a structure for directly cooling a portable terminal according to a sixth embodiment of the present disclosure.

As shown in FIGS. 20 and 21, a cooling fan 660 according to the sixth embodiment of the present disclosure is configured to introduce air between the portable terminal 10 put on a charging body 610 and the charging body 610 be introduced into the charging body 610 or discharge air inside the charging body 610 to the outside of the charging body 610.

The cooling fan 660 may be placed outside the charging body 610 formed with an outlet hole 630 as shown in FIG. 20. When the cooling fan 660 operates, air between the portable terminal 10 put on the charging body 610 and the charging body 610 is introduced into the charging body 610 and then flows toward the outlet hole 630.

The reference numeral of ‘690’ indicates supporters which are formed to have a predetermined length in a protruding direction of a direct cooling projection 640 at outer lateral sides of the charging body 610, and hold the lateral sides of the portable terminal 10 so as to prevent the portable terminal 10 from freely falling from the top of the charging body 610 when the portable terminal 10 is put on the charging body 610.

With this structure, when the portable terminal 10 is put on the charging body 610, the side supporters 690 hold or support both lateral sides of the portable terminal 10 to thereby prevent the portable terminal 10 from freely falling from the charging body 610.

According to one aspect of the present disclosure, a wireless charger having a structure for directly cooling a portable terminal can effectively dissipate heat generated when the portable terminal is charging wirelessly by the wireless charger, in which a built-in cooling fan designed for dissipating heat from the existing wireless charger can dissipate heat from not only the wireless charger but also the portable terminal.

Although a few exemplary embodiments of the present disclosure have been shown and described, these are for illustrative purpose only and it will be appreciated by those skilled in the art that changes may be made in these embodiments without departing from the principles and spirit of the invention, the scope of which is defined in the appended claims and their equivalents.

[Reference Numerals]

| | |
|---|---|
| 100: wireless charger | 110: charging body |
| 120: top hole | 130: outlet hole |
| 140: direct cooling projection | 150: support projection |
| 160: cooling fan | 170: gap |
| 10: portable terminal | 11: charging patch |
| 101: power transmission coil | |

What is claimed is:

1. A wireless charger for wirelessly charging a portable terminal, having a structure for directly cooling the portable terminal, the wireless charger comprising:
a charging body on which the portable terminal to be charged is put;
a top hole which is formed to penetrate a top of the charging body and makes air between the portable terminal put on the charging body and the charging body flow into the charging body so that the portable terminal can be directly cooled;
a cooling fan by which the air between the portable terminal put on the charging body and the charging body is introduced into the charging body; and
an outlet hole through which the air introduced into the charging body by the cooling fan is discharged outward from the charging body.

2. The wireless charger according to claim 1, wherein the charging body comprises a direct cooling projection protruding at a predetermined height to form a gap in which the air can flow between the charging body and the portable terminal when the portable terminal to be charged is put on the charging body.

3. The wireless charger according to claim 1, wherein:
the top hole is formed to have a trapezoidal shape that becomes wider in a direction from an inner opening side of the charging body toward an outer opening side of the charging body, and
the outlet hole is formed to have a trapezoidal shape that becomes narrower in a direction from an inner opening side of the charging body toward an outer opening side of the charging body.

4. The wireless charger according to claim 1, wherein the top hole is formed in plural leaving a space there between on the top of the charging body, and
between the plurality of top holes is provided an eddy member to guide air inside the charging body to eddy and go back to the inside of the charging body when the air is discharged outward via the top hole.
